(19) United States
(12) Patent Application Publication
(10) Pub. No.: US 2022/0025514 A1
(43) Pub. Date: Jan. 27, 2022

(54) Precursors And Processes For The Thermal ALD Of Cobalt Metal Thin Films

(71) Applicant: WAYNE STATE UNIVERSITY, DETROIT, MI (US)

(72) Inventors: Charles H. WINTER, Bloomfield Hills, MI (US); Jonathan HOLLIN, Detroit, MI (US); Nyi Myat Khine LINN, Detroit, MI (US)

(21) Appl. No.: 16/934,514

(22) Filed: Jul. 21, 2020

(51) Int. Cl. C23C 16/18; C07F 15/06; C07F 15/04; C07F 15/02; C07F 11/00; C07F 13/00; C07F 3/06; C23C 16/455

(52) U.S. Cl. CPC C23C 16/18; C07F 15/065; C07F 15/045; C23C 16/45553; C07F 11/005; C07F 13/005; C07F 3/06; C07F 15/025

(57) ABSTRACT

A method for depositing a metal layer includes a step of contacting a surface of an electrically conductive substrate with a vapor of a metal-containing compound for a first predetermined pulse time to form a modified surface on the electrically conductive substrate. The metal-containing compound is a metal diketonate or a structurally similar compound. The modified surface is contacted with a vapor of a reducing agent that is a hydrazine or a hydrazine derivative for a second predetermined pulse time to form a metal-containing film on the surface of the electrically conductive substrate. Characteristically, the metal-containing film includes the metal atom in a zero oxidation state in an amount greater than 80 mole percent.

### TECHNICAL FIELD

In at least one aspect, the present invention relates to methods for forming metal layers by atomic layer deposition at low temperatures.

### BACKGROUND

In the microelectronics industry, smaller device dimensions require the development of new materials. Cobalt has utility as a barrier layer in amorphous CoTix (x=18-83%) alloys. Cobalt and CoTix can replace current W/Ti/TiN contact plugs and other liners in integrated circuits. In this regard, the ALD of cobalt metal is required for deposition in high aspect ratio features. Deposition of cobalt metal is difficult due to the negative electrochemical potential of Co(II), (Co(II)↔Co(0), E°=−0.28 V)

Moreover, ALD growth of cobalt metal is likely to be required for use in future electronics applications such as in magnetic materials, as an intermediate in the deposition of CoSiₓ contacts, for liners and caps of copper features in microelectronics devices, and the replacement of copper in high aspect ratio features

Accordingly, there is a need for an improved process for forming cobalt and similar metal films for microelectronic applications.

### SUMMARY

In at least one aspect, the present invention provides a method for depositing a metal layer. The method includes a step of contacting a surface of an electrically conductive substrate with a vapor of a metal-containing compound for a first predetermined pulse time to form a modified surface on the electrically conductive substrate. The metal-containing compound is described by formulae 1.1 or 1.2 or oligomers thereof:

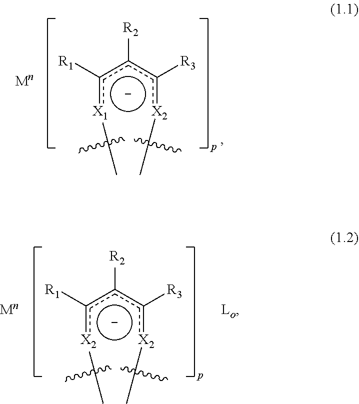

wherein:

M is a metal atom;

n is the formal charge of M;

X₁ and X₂ are each independently O or N—R₄;

L is a neutral or anionic ligand;

o is 1, 2, or 3;

p is an integer such that the overall formal charge of the metal-containing compound is 0;

R₁, R₂, R₃, and R₄ are each independently H, C₁-C₅ alkyl, perfluorinated C₁-C₅ alkyl, partially fluorinated C₁-C₅ alkyl, or —Si(R⁵)₃; and

R⁵ is H, halo, C₁-C₅ alkyl, perfluorinated C₁-C₅ alkyl, or partially fluorinated C₁-C₅ alkyl. The modified surface is then contacted with a vapor of a reducing agent having formula 2 for a second predetermined pulse time to form a metal-containing film on the surface of the electrically conductive substrate. The metal-containing film includes the metal atom is in a zero oxidation state in an amount greater than 80 mole percent:

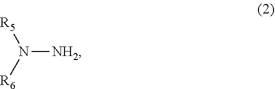

wherein R⁵ and R⁶ are each independently H or C₁-C₅ alkyl and wherein the electrically conductive substrate is at a first predetermined temperature during these two steps.

In another embodiment, a method for depositing a metal layer is provided. The method includes a step of contacting a surface of an electrically conductive substrate with a vapor of a metal-containing compound for a first predetermined pulse time to form a modified surface on the electrically conductive substrate. The metal-containing compound is described by formula 3.3:

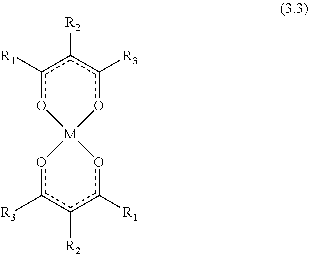

wherein:

M is a metal atom selected from the group consisting of Co, Cr, Mn, Fe, Zn, or Ni.

R₁, R₂, and R₃ are each independently H, C₁-C₅ alkyl, perfluorinated C₁-C₅ alkyl, partially fluorinated C₁-C₅ alkyl, or —Si(R⁴)₃. The modified surface is contacted with a vapor of a reducing agent having formula 2 for a second predetermined pulse time to form a metal-containing film on the surface of the electrically conductive substrate:

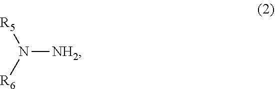

wherein R⁵ and R⁶ are each independently H or C₁-C₅ alkyl. Characteristically, the metal-containing film includes the metal atom in a zero oxidation state in an amount greater than 80 mole percent, wherein the electrically conductive substrate is at a first predetermined temperature during the two steps set forth above. Moreover, these two steps are successively performed a plurality of times until the metal-containing film is within a predetermined thickness range.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

For a further understanding of the nature, objects, and advantages of the present disclosure, reference should be had to the following detailed description, read in conjunction with the following drawings, wherein like reference numerals denote like elements and wherein:

FIG. 1. Schematic illustration of an atomic layer deposition system for depositing metal films from metal diketonates.

FIG. 2A. Chemical structures of cobalt β-ketoiminates and β-diketiminates.

FIG. 2B. Table showing the melting point, decomposition temperature, and the sublimation temperature for the compounds of FIG. 2A.

FIG. 2C. Plot showing thermogravimetric analysis for the compounds of FIG. 2A.

FIG. 3A. Chemical structures of cobalt hexafluoroacetylacetonate and related adducts.

FIG. 3B. Table showing the melting point, decomposition temperature, and the sublimation temperature for the compounds of FIG. 3A.

FIG. 3C. Plot showing thermogravimetric analysis for the compounds of FIG. 3A.

FIG. 4A. Chemical structures of cobalt tetramethylheptanedionate and related adducts.

FIG. 4B. Table showing the melting point, decomposition temperature, and the sublimation temperature for the compounds of FIG. 4A.

FIG. 4C. Plot showing thermogravimetric analysis for the compounds of FIG. 4A.

FIG. 5A. Chemical structures of adducts of cobalt acetylacetonate and thienoyltrifluoroacetonate and cobalt tris(pyrazolyl)borate.

FIG. 5B. Table showing the melting point, decomposition temperature, and the sublimation temperature for the compounds of FIG. 5A.

FIG. 5C. Plot showing thermogravimetric analysis for the compounds of FIG. 5A.

FIG. 6. Growth rate as a function of temperature for Cobalt Metal ALD with Co(thd)₂.

FIG. 7A. Saturation curve for Co(thd)₂.

FIG. 7B. Saturation curve for Me₂NNH₂.

FIG. 8. Grazing incidence X-ray diffraction data was collected for a film grown on copper for 2000 cycles.

FIG. 9A. XPS Depth Profile plots for 22 nm thick cobalt metal film deposited at 265° C. from Co(thd)₂.

FIG. 9B. XPS Depth Profile table for 22 nm thick cobalt metal film deposited at 265° C. from Co(thd)₂. The regions showing Co metal film is selected.

FIG. 10A. XPS Depth Profile plots for 18 nm thick cobalt metal film deposited at 275° C. from Co(thd)₂.

FIG. 10B. XPS Depth Profile table for 18 nm thick cobalt metal film deposited at 275° C. from Co(thd)₂. The regions showing Co metal film is selected.

FIG. 11A. XPS Depth Profile plots for 38 nm thick cobalt metal film deposited at 285° C. from Co(thd)₂.

FIG. 11B. XPS Depth Profile table for 38 nm thick cobalt metal film deposited at 285° C. from Co(thd)₂. The regions showing Co metal film is selected.

FIG. 12A. XPS Depth Profile plots for 30 nm thick cobalt metal film deposited at 285° C. from Co(thd)₂ with annealing.

FIG. 12B. XPS Depth Profile table for 30 nm thick cobalt metal film deposited at 285° C. from Co(thd)₂ with annealing. The regions showing Co metal film is selected.

FIG. 13A. Atomic Force Microscopy Data for a thick cobalt metal film deposited at 265° C. from Co(thd)₂ showing an RMS roughness value of 2.97 nm.

FIG. 13B. Atomic Force Microscopy Data for a thick cobalt metal film deposited at 275° C. from Co(thd)₂ showing an RMS roughness 4.35 nm.

FIG. 13C. Atomic Force Microscopy Data for a thick cobalt metal film deposited at 285° C. from Co(thd)₂ showing an RMS roughness value of 2.87 nm.

FIG. 13D. Atomic Force Microscopy Data for a thick cobalt metal film deposited at 285° C. from Co(thd)₂ with a 400° C. anneal showing an RMS roughness value of 3.26 nm.

FIG. 14. Plots of the growth rate versus the number of cycles for a cobalt metal film deposited at 285° C. from Co(thd)₂.

FIG. 15. Resistivity data for films grown with an increasing number of ALD cycles.

### DETAILED DESCRIPTION

Reference will now be made in detail to presently preferred compositions, embodiments and methods of the present invention, which constitute the best modes of practicing the invention presently known to the inventors. The Figures are not necessarily to scale. However, it is to be understood that the disclosed embodiments are merely exemplary of the invention that may be embodied in various and alternative forms. Therefore, specific details disclosed herein are not to be interpreted as limiting, but merely as a representative basis for any aspect of the invention and/or as a representative basis for teaching one skilled in the art to variously employ the present invention.

Except in the examples, or where otherwise expressly indicated, all numerical quantities in this description indicating amounts of material or conditions of reaction and/or use are to be understood as modified by the word “about” in describing the broadest scope of the invention. Practice within the numerical limits stated is generally preferred. Also, unless expressly stated to the contrary: all R groups (e.g. Rᵢ where i is an integer) include hydrogen, alkyl, lower alkyl, C₁₋₆ alkyl, C₆₋₁₀ aryl, C₆₋₁₀ heteroaryl, —NO₂, —NH₂, —N(R′R″), —N(R′R″R′″)⁺L⁻, Cl, F, Br, —CF₃, —CCl₃, —CN, —SO₃H, —PO₃H₂, —COOH, —CO₂R′, —COR′, —CHO, —OH, —OR′, —O⁻M⁺, —SO₃M⁺, —PO₃⁻M⁺, —COO⁻M⁺, —CF₂H, —CF₂R′, —CFH₂, and —CFR′R″ where R′, R″ and R′″ are C₁₋₁₀ alkyl or C₆₋₁₈ aryl groups; single letters (e.g., “n” or “o”) are 1, 2, 3, 4, or 5; in the compounds disclosed herein a CH bond can be substituted with alkyl, lower alkyl, C₁₋₆ alkyl, C₆₋₁₀ aryl, C₆₋₁₀ heteroaryl, —NO₂, —NH₂, —N(R′R″), —N(R′R″R′″)⁺L⁻, Cl, F, Br, —CF₃, —CCl₃, —CN, —SO₃H, —PO₃H₂, —COOH, —CO₂R′, —COR′, —CHO, —OH, —OR′, —O⁻M⁺, —SO₃⁻M⁺, —PO₃⁻M⁺, —COO⁻M⁺, —CF₂H, —CF₂R′, —CFH₂, and —CFR′R″ where R′, R″ and R′″ are C₁₋₁₀ alkyl or C₆₋₁₈ aryl groups; percent, “parts of,” and ratio values are by weight; the term “polymer” includes “oligomer,” “copolymer,” “terpolymer,” and the like; molecular weights provided for any polymers refers to weight average molecular weight unless otherwise indicated; the description of a group or class of materials as suitable or preferred for a given purpose in connection with the invention implies that mixtures of any two or more of the members of the group or class are equally suitable or preferred; description of constituents in chemical terms refers to the constituents at the time of addition to any combination specified in the description, and does not necessarily preclude chemical interactions among the constituents of a mixture once mixed; the first definition of an acronym or other abbreviation applies to all subsequent uses herein of the same abbreviation and applies mutatis mutandis to normal grammatical variations of the initially defined abbreviation; and, unless expressly stated to the contrary, measurement of a property is determined by the same technique as previously or later referenced for the same property.

It must also be noted that, as used in the specification and the appended claims, the singular form “a,” “an,” and “the” comprise plural referents unless the context clearly indicates otherwise. For example, reference to a component in the singular is intended to comprise a plurality of components.

As used herein, the term “about” means that the amount or value in question may be the specific value designated or some other value in its neighborhood. Generally, the term “about” denoting a certain value is intended to denote a range within +/−5% of the value. As one example, the phrase “about 100” denotes a range of 100+/−5, i.e., the range from 95 to 105. Generally, when the term “about” is used, it can be expected that similar results or effects according to the invention can be obtained within a range of +/−5% of the indicated value.

As used herein, the term “and/or” means that either all or only one of the elements of said group may be present. For example, “A and/or B” shall mean “only A, or only B, or both A and B”. In the case of “only A”, the ern also covers the possibility that. B is absent, i.e. “only A, but not B”.

It is also to be understood that this invention is not limited to the specific embodiments and methods described below, as specific components and/or conditions may, of course, vary. Furthermore, the terminology used herein is used only for the purpose of describing particular embodiments of the present invention and is not intended to be limiting in any way.

The term “comprising” is synonymous with “including,” “having,” “containing,” or “characterized by.” These terms are inclusive and open-ended and do not exclude additional, unrecited elements or method steps.

The phrase “consisting of” excludes any element, step, or ingredient not specified in the claim. When this phrase appears in a clause of the body of a claim, rather than immediately following the preamble, it limits only the element set forth in that clause; other elements are not excluded from the claim as a whole.

The phrase “consisting essentially of” limits the scope of a claim to the specified materials or steps, plus those that do not materially affect the basic and novel characteristic(s) of the claimed subject matter.

The phrase “composed of” means “including” or “consisting of” Typically, this phrase is used to denote that an object is formed from a material.

With respect to the terms “comprising,” “consisting of,” and “consisting essentially of,” where one of these three terms is used herein, the presently disclosed and claimed subject matter can include the use of either of the other two terms.

The term “one or more” means “at least one” and the term “at least one” means “one or more.” The terms “one or more” and “at least one” include “plurality” as a subset.

The term “substantially,” “generally,” or “about” may be used herein to describe disclosed or claimed embodiments. The term “substantially” may modify a value or relative characteristic disclosed or claimed in the present disclosure. In such instances, “substantially” may signify that the value or relative characteristic it modifies is within +0%, 0.1%, 0.5%, 1%, 2%, 3%, 4%, 5% or 10% of the value or relative characteristic.

It should also be appreciated that integer ranges explicitly include all intervening integers. For example, the integer range 1-10 explicitly includes 1, 2, 3, 4, 5, 6, 7, 8, 9, and 10. Similarly, the range 1 to 100 includes 1, 2, 3, 4 . . . 97, 98, 99, 100. Similarly, when any range is called for, intervening numbers that are increments of the difference between the upper limit and the lower limit divided by 10 can be taken as alternative upper or lower limits. For example, if the range is 1.1. to 2.1 the following numbers 1.2, 1.3, 1.4, 1.5, 1.6, 1.7, 1.8, 1.9, and 2.0 can be selected as lower or upper limits.

In the examples set forth herein, concentrations, temperature, and reaction conditions (e.g., pressure, pH, flow rates, etc.) can be practiced with plus or minus 50 percent of the values indicated rounded to or truncated to two significant figures of the value provided in the examples. In a refinement, concentrations, temperature, and reaction conditions (e.g., pressure, pH, flow rates, etc.) can be practiced with plus or minus 30 percent of the values indicated rounded to or truncated to two significant figures of the value provided in the examples. In another refinement, concentrations, temperature, and reaction conditions (e.g., pressure, pH, flow rates, etc.) can be practiced with plus or minus 10 percent of the values indicated rounded to or truncated to two significant figures of the value provided in the examples.

For all compounds expressed as an empirical chemical formula with a plurality of letters and numeric subscripts (e.g., CH₂O), values of the subscripts can be plus or minus 50 percent of the values indicated rounded to or truncated to two significant figures. For example, if CH₂O is indicated, a compound of formula C_{(0.8-1.2)}H_{(1.6-20.4)}O_{(0.8-1.2)}. In a refinement, values of the subscripts can be plus or minus 30 percent of the values indicated rounded to or truncated to two significant figures. In still another refinement, values of the subscripts can be plus or minus 20 percent of the values indicated rounded to or truncated to two significant figures.

The term “alkali metal” means lithium, sodium, potassium, rubidium, caesium, and francium.

The “alkaline earth metal” means chemical elements in group 2 of the periodic table. The alkaline earth metals include beryllium, magnesium, calcium, strontium, barium, and radium.

The term “transition metal” means an element whose atom has a partially filled d sub-shell, or which can give rise to cations with an incomplete d sub-shell. Examples of transition metals includes scandium, titanium, vanadium, chromium, manganese, iron, cobalt, nickel, copper, yttrium, zirconium, niobium, molybdenum, technetium, ruthenium, rhodium, palladium, silver, hafnium, tantalum, tungsten, rhenium, osmium, iridium, platinum, and gold.

The term “lanthanide” or lanthanoid series of chemical elements” means an element with atomic numbers 57-71. The lanthanides metals include lanthanum, cerium, praseodymium, samarium, europium, gadolinium neodymium, promethium, terbium, dysprosium, holmium, erbium, thulium, ytterbium, or lutetium.

The term “actinide” or “actinide series of chemical elements” means chemical elements with atomic numbers from 89 to 103. Examples of actinides include actinium, thorium, protactinium, uranium, neptunium, and plutonium.

The term “post-transition metal” means gallium, indium, tin, thallium, lead, bismuth, zinc, cadmium, mercury, aluminum, germanium, antimony, or polonium.

The term “metal” as used herein means an alkali metal, an alkaline earth metal, a transition metal, a lanthanide, an actinide, or a post-transition metal.

Throughout this application, where publications are referenced, the disclosures of these publications in their entireties are hereby incorporated by reference into this application to more fully describe the state of the art to which this invention pertains.

Abbreviations:

“acac” means acetylacetonate.

“ALD” means atomic layer deposition.

“Cy” means cyclohexyl.

“hfac” means hexafluoroacetylacetonate.

“Nacac” means β-ketoiminate.

“TEEDA” means N,N, N′,N′-Tetraethylethylenediamine.

“TMEDA” means tetramethylethylenediamine.

“TMPDA” means tetramethylpropylenediamine

“thd” means 2,2,6,6-tetramethyl-3,5-heptanediketonate.

“Tp” means tris(pyrazolyl)borate.

“tta” means 2-thenoyltrifluoroacetonate.

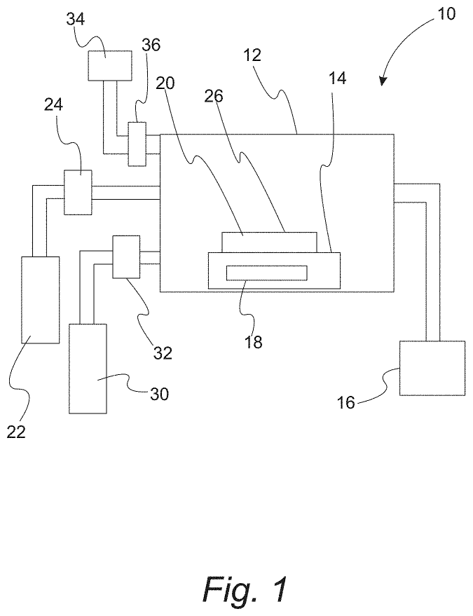

In an embodiment of the present embodiment, a method for depositing a thin film on a surface of a substrate is provided. With reference to FIG. 1, deposition system 10 includes a reaction chamber 12, substrate holder 14, and vacuum pump 16. In a refinement, deposition system 10 is an ALD reactor. Typically, the substrate is heated via heater 18 to a first predetermined temperature. The method has a deposition cycle that is repeated a plurality of times in order to build up the thickness of a metal film on substrate 20 to a predetermined thickness. Each deposition cycle comprises a step (step b) of contacting electrically substrate 20 with a vapor of a metal-containing described by formulae 1.1 or 1.2 or oligomers thereof:

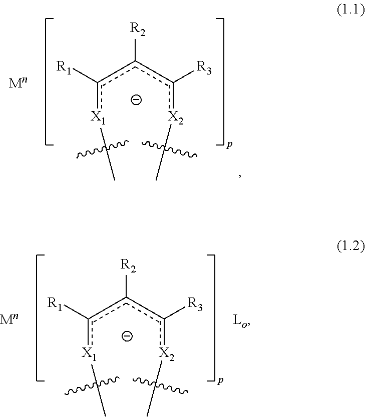

wherein:

M is a metal atom;

n is the formal charge of M (e.g., 0, 1+, 2+, 3+, 4+, 5+, 6+);

X₁ and X₂ are each independently O or N—R₄;

L is a neutral or anionic ligand;

o is 1, 2, or 3;

p is an integer such that the overall formal charge of the metal-containing compound is 0;

R₁, R₂, R₃, and R₄ are each independently H, C₁-C₅ alkyl, perfluorinated C₁-C₅ alkyl, partially fluorinated C₁-C₅ alkyl, or —Si(R⁵)₃; and

R⁵ is H, halo, C₁-C₅ alkyl, perfluorinated C₁-C₅ alkyl, or partially fluorinated C₁-C₅ alkyl. Note, the wavy lines crossing a straight line indicated the attachment points (e.g., bond-forming) to the metal M. In a refinement, n is 1+, 2+, or 3+; o is 0, 1, 2, or 3; and p is 1, 2, or 3. In another refinement, n is 1+, 2+, or 3+ and p is 1, 2, or 3.

It should be appreciated that a variety of different ligands may be used for L. For example, L can be a two-electron ligand, a multidentate ligand (e.g., a bidentate ligand), charged ligand (e.g., −1 charged), a neutral ligand, and combinations thereof. A specific example for L is Me₂NCH₂CH₂NMe₂. Although o gives the number of ligands, each ligand need not be the same for values of o greater than 2. In a refinement, R₁, R₂, R₃, and R₄ are each independently H or C₁₋₄ alkyl. Examples of useful alkyl groups include, but are not limited to, methyl, ethyl, n-propyl, isopropyl, n-butyl, t-butyl, isobutyl, sec-butyl, and the like. In another refinement, R₁, R₂, R₃, and R₄ are each independently H, methyl, ethyl, propyl, n-butyl, sec-butyl, isobutyl, or t-butyl. In still another refinement, R₂ is H and R₁, R₃, and R₄ are each independent methyl, ethyl, propyl, n-butyl, sec-butyl, isobutyl, or t-butyl. In yet another refinement, R₁, R₃, and R₄ are methyl or t-butyl and R² is hydrogen.

In a refinement of the present embodiment, M is a transition metal atom typically in the 0 to +6 oxidation state. In a further refinement, M is a transition metal atom in the +1 to +3 oxidation state. In still a further refinement, M is a transition metal atom in the +2 oxidation state. Examples of useful metals for M include, but are not limited to, silver, palladium, platinum, rhodium, iridium, cobalt, ruthenium, manganese, nickel, zinc, and copper. In a further refinement, M is Co(II), Cr, Mn, Fe, Zn, or Ni. For example, M can be Co(II), Cr(II), Mn(II), Fe(II), Zn(II), or Ni(II).

Still referring to FIG. 1, the vapor is introduced from precursor source 22 into the reaction chamber 12 for a first predetermined pulse time. In a variation, the compound from precursor source 22 is introduced into chamber 12 by direct liquid injection. The first predetermined pulse time should be sufficiently long that available binding sites on the substrate surface (coated with metal layers or uncoated) are saturated (i.e., metal-containing compound attached). Typically, the first predetermined pulse time is from 1 second to 20 seconds. The first predetermined pulse time is controlled via control valve 24. At least a portion of the vapor of the metal-containing compound modifies (e.g., adsorbs or reacts with) substrate surface 26 to form the first modified surface. In a refinement, the reaction chamber 12 is then purged with an inert gas for a first purge time. The inert gas is provided from purge gas source 30 and controlled by control valve 32. The first purge time is sufficient to remove the metal-containing compound from the reaction chamber 12 and is typically from 0.5 seconds to 2 minutes. Alternatively, the purging can be replaced with or supplemented by a pumping step.

In the next reaction step (step b) of the deposition cycle, the modified surface is contacted with a vapor of a reducing agent having formula 2 for a second predetermined pulse time to form a metal-containing film on the surface of the electrically conductive substrate,

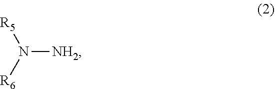

wherein R⁵ and R⁶ are each independently H or C₁-C₅ alkyl. Examples of the reducing agent include, but are not limited to, tBuNHNH₂, (CH₃)₂NNH₂, or H₂NNH₂ (hydrazine). The reducing agent can be provided from reducing agent source 34 which is controlled by control valve 36. In a refinement, the reaction chamber 12 is then purged with an inert gas for a second purge time as set forth above. The second purge time is sufficient to remove the metal-containing compound from the reaction chamber 12 and is typically from 0.5 seconds to 2 minutes. As set forth above, this purging step can be replaced by or supplemented with a pumping step.

During each deposition cycle, the substrate temperature is typically maintained at the first predetermined temperature for steps a) and b). In a refinement, the first predetermined temperature is between 200 to 350° C. In a further refinement, steps a) and b) are performed at a first predetermined pressure of about 0.1 millitorr to 100 Torr.

Characteristically, the metal-containing film includes the metal atom in a zero oxidation state in an amount greater than 80 mole percent. In a refinement, the metal-containing film includes metastable metal nitrides in an amount less than 20 mole percent. In a further refinement, the metal-containing film includes the metal atom in a zero oxidation state in an amount greater than 90 mole percent and metastable metal nitrides in an amount less than 10 mole percent.

In a variation, the method further includes a step of annealing the metal-containing film at a second predetermined temperature for a sufficient time that the metal-containing film includes the metal atom in the zero oxidation state in an amount greater than 98 mole percent. Characteristically, the second predetermined temperature is greater than the first predetermined temperature. In a refinement, the second predetermined temperature is greater than in increasing order of preference, 300° C., 310° C., 325° C., or 330° C. Typically, the second predetermined temperature is less than about 400° C.

In a variation, the metal-containing compound is described by formulae 3.1, 3.2, or 3.3:

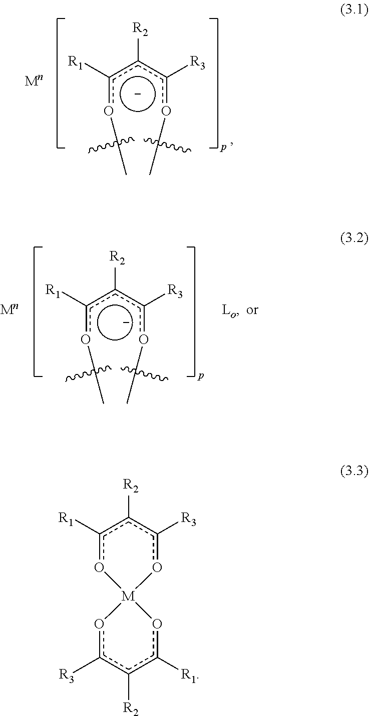

Details for R₁, R₂, R₃, and M are the same as above. In a refinement of the compounds having formula 3.1, 3.2, or 3.3, R₁, R₂, and R₃ are each independently H or C₁₋₄ alkyl. Examples of useful alkyl groups include, but are not limited to, methyl, ethyl, n-propyl, isopropyl, n-butyl, t-butyl, isobutyl, sec-butyl, and the like. In another refinement, R₁, R₂, and R₃ are each independently H, methyl, ethyl, propyl, n-butyl, sec-butyl, isobutyl, or t-butyl. In still another refinement, R₂ is H and R₁ and R₃ are each independent methyl, ethyl, propyl, n-butyl, sec-butyl, isobutyl, or t-butyl. In yet another refinement, R₁ and R₃ are methyl or t-butyl and R² is hydrogen.

In another variation, the metal-containing compound is described by formulae 4.1, 4.2, 4.3, or 4.4:

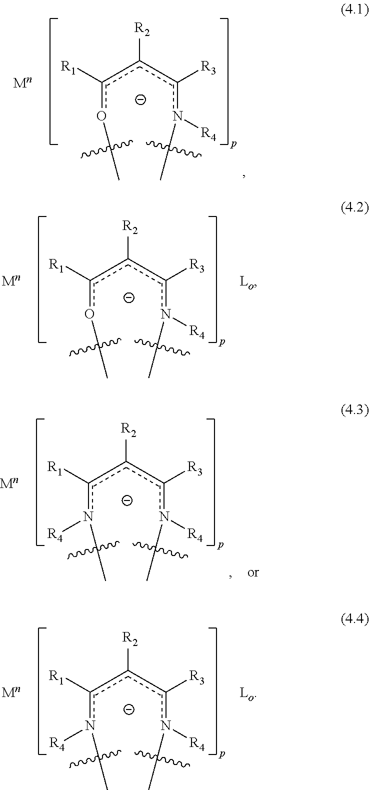

Details for R₁, R₂, R₃, R₄ and M are the same as above. In a refinement of the compounds having formulae 4.1, 4.2, 4.3, or 4.4, R₁, R₂, R₃, and R₄ are each independently H or C₁₋₄ alkyl. Examples of useful alkyl groups include, but are not limited to, methyl, ethyl, n-propyl, isopropyl, n-butyl, t-butyl, isobutyl, sec-butyl, and the like. In another refinement, R₁, R₂, R₃, and R₄ are each independently H, methyl, ethyl, propyl, n-butyl, sec-butyl, isobutyl, or t-butyl. In still another refinement, R₂ is H and R₁, R₃, and R₄ are each independent methyl, ethyl, propyl, n-butyl, sec-butyl, isobutyl, or t-butyl. In yet another refinement, R₁ R₃, and R₄ are methyl or t-butyl and R² is hydrogen.

In a variation, the electrically conductive substrate has an electrical resistivity that is less than about, in increasing order of preference 1×10⁻² ohm-m, 1×10⁻³ ohm-m, 1×10⁻⁴ ohm-m, 1×10⁻⁵ ohm-m, 1×10⁻⁶ ohm-m, 1×10⁻⁷ ohm-m. Most resistivities are greater than about 1×10⁻⁹ ohm-m. In a refinement, the electrically conductive substrate includes one or more surfaces composed of silicon, titanium nitride, tantalum nitride, or a metal. In a further refinement, the electrically conductive substrate includes one or more surfaces composed of copper or ruthenium. Examples of useful electrically conductive substrates include, but are not limited to, silicon (with the native oxide removed), titanium nitride coated substrates, tantalum nitride coated substrate, metal-coated base substrates, metal substrates, and silicon-coated substrates. Advantageously, the metal-containing film grows selectively on surfaces of the one or more electrically conductive films. In a refinement, the electrically conductive substrate includes one or more electrically conductive films disposed over a base substrate.

It should be appreciated that pulse times, purge times, and pump times also depend on the properties of the chemical precursors and the geometric shape of the substrates. Thin film growth on flat substrates uses short pulse and purge times and/or pump times, but pulse and purge times and/or pump times here too in ALD growth on 3-dimensional substrates can be very long. Therefore, in one refinement, pulse times and purge times and/or pump times are each independently from about 0.0001 to 200 seconds. In another refinement, pulse and purge times and/or pump times are each independently from about 0.1 to about 10 seconds.

In another variation, steps a) and b) are repeated a plurality of times. For example the deposition cycle can be repeated 1 to 5000 times. The desired metal film thickness depends on the number of deposition cycles. For example, for a cobalt metal film 1000 cycles typically results in a thickness of about 500 angstroms. Therefore, in a refinement, the deposition cycle is repeated a plurality of times to form a predetermined thickness of the metal film. In a further refinement, the deposition cycle is repeated a plurality of times to form a metal film having a thickness from about 5 nanometers to about 200 nanometers. In still another refinement, the deposition cycle is repeated a plurality of times to form a metal film having a thickness from about 5 nanometers to about 300 nanometers. In yet another refinement, the deposition cycle is repeated a plurality of times to form a metal film having a thickness from about 5 nanometers to about 100 nanometers.

During film formation by the method of the present embodiment, the substrate temperature will be at a temperature suitable to the properties of the chemical precursor(s) and film to be formed. In a refinement of the method, the substrate is set to a temperature from about 0 to 1000° C. In another refinement of the method, the substrate has a temperature from about 150 to 450° C. In another refinement of the method, the substrate has a temperature from about 150 to 400° C. In still another refinement of the method, the substrate has a temperature from about 200 to 350° C. In another refinement of the method, the substrate has a temperature from about 200 to 300° C.

Similarly, the pressure during film formation is set at a value suitable to the properties of the chemical precursors and film to be formed. In one refinement, the pressure is from about 1×10⁻⁶ Torr to about 760 Torr. In another refinement, the pressure is from about 0.1 millitorr to about 100 Torr. In another refinement, the pressure is from about 0.1 millitorr to about 100 Torr. In still another refinement, the pressure is from about 1 to about 10 millitorr. In yet another refinement, the pressure is from about 1 to 20 millitorr.

The following examples illustrate the various embodiments of the present invention. Those skilled in the art will recognize many variations that are within the spirit of the present invention and scope of the claims.

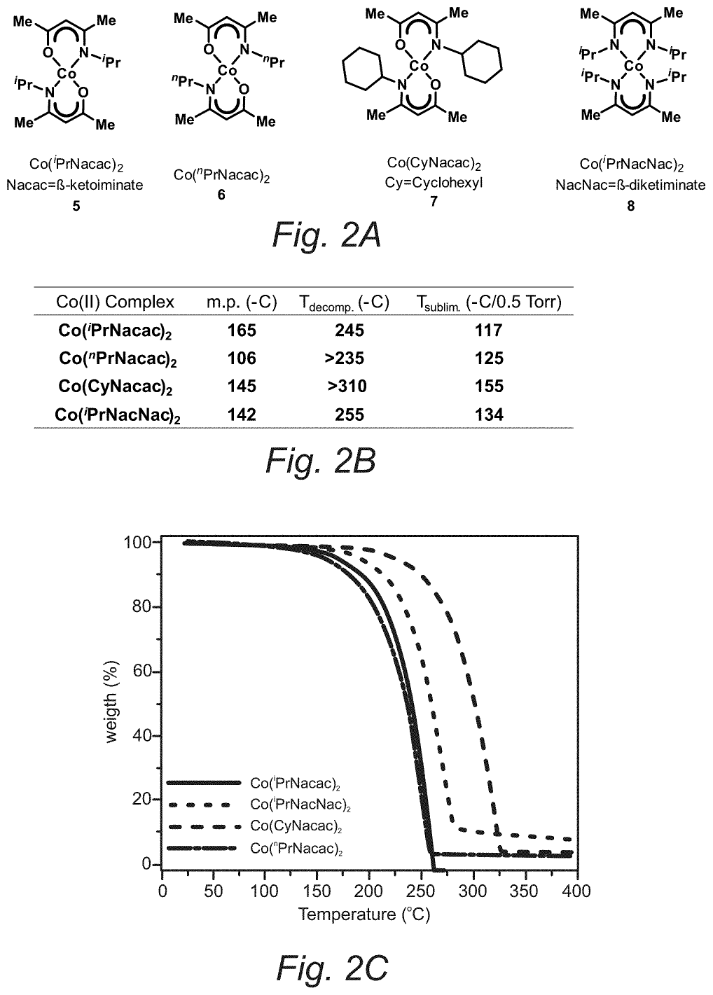

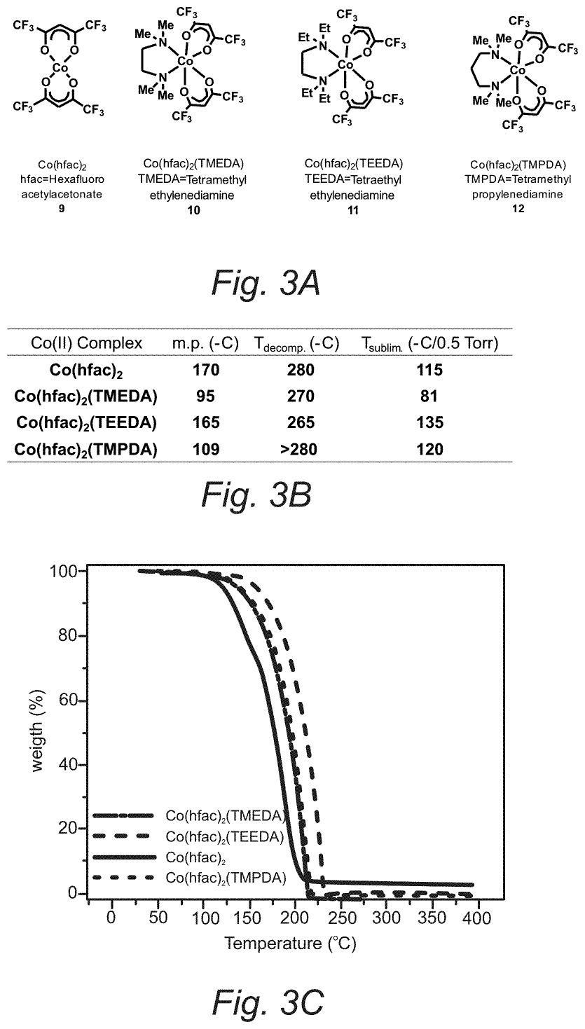

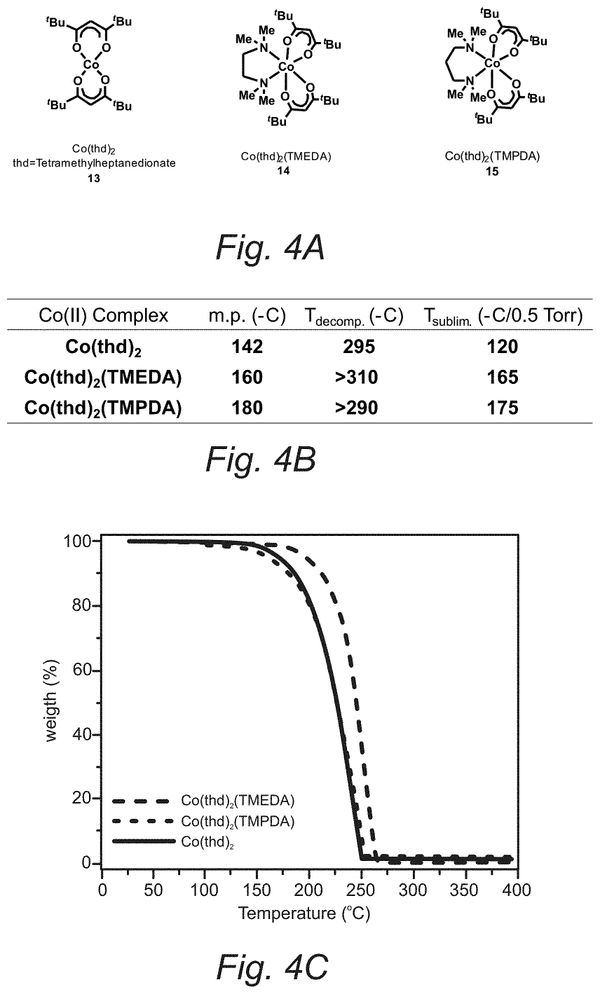

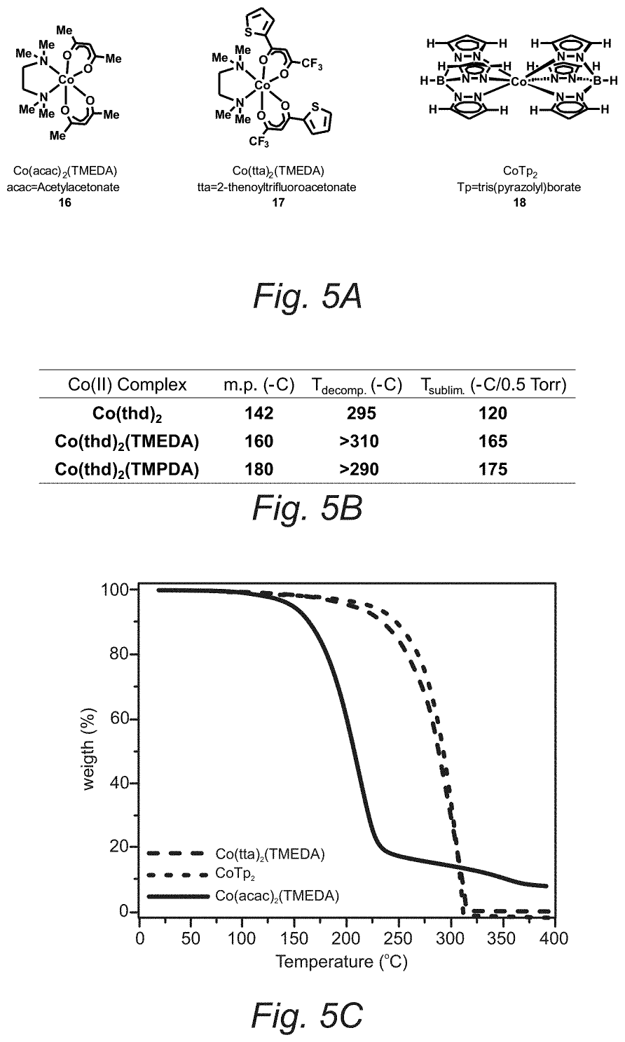

FIGS. 2 to 5 provides chemical structures for compounds that can be used in the methods set forth herein. FIG. 2A provides chemical structures of cobalt β-ketoiminates and β-diketiminates. FIG. 2B provides a table showing the melting point, decomposition temperature, and the sublimation temperature for the compounds of FIG. 2A. FIG. 2C provides plots showing thermogravimetric analysis for the compounds of FIG. 2A. FIG. 3A provides chemical structures of cobalt hexafluoroacetylacetonate and related adducts. FIG. 3B provides a table showing the melting point, decomposition temperature, and the sublimation temperature for the compounds of FIG. 3A. FIG. 3C provides plots showing thermogravimetric analysis for the compounds of FIG. 3A. FIG. 4A provides chemical structures of cobalt tetramethylheptanedionate and related adducts. FIG. 4B provides a table showing the melting point, decomposition temperature, and the sublimation temperature for the compounds of FIG. 4A. FIG. 4C provides plots showing thermogravimetric analysis for the compounds of FIG. 4A. FIG. 5A provides chemical structures of adducts of cobalt acetylacetonate and thienoyltrifluoroacetonate and cobalt bis(pyrazolyl)borate. FIG. 5B provides a table showing the melting point, decomposition temperature, and the sublimation temperature for the compounds of FIG. 5A. FIG. 5C provides plots showing thermogravimetric analysis for the compounds of FIG. 5A. In general, the compounds described in FIG. 2-5 possess appropriate melting points, sublimation temperatures, and decomposition profiles to be used in ALD process.

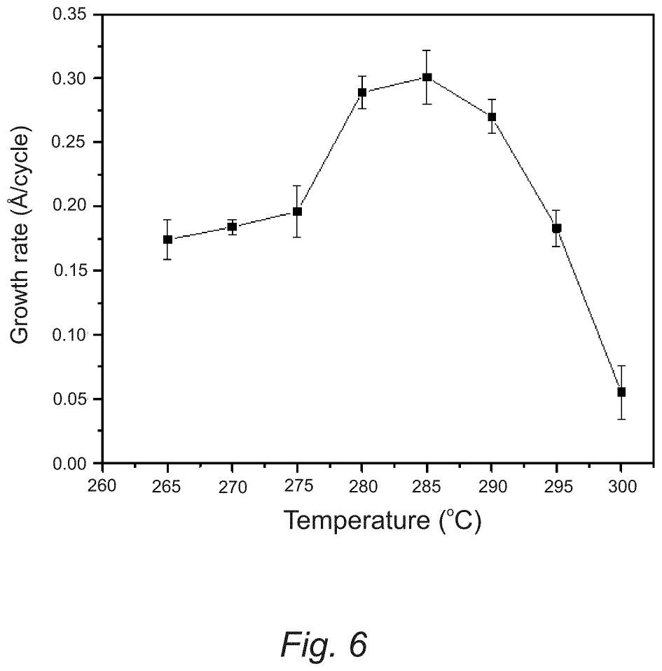

FIG. 6 provides growth rate plots as a function of temperature for cobalt metal ALD with Co(thd)₂. For these experiments, cobalt metal was deposited selectively on ruthenium and copper substrates. An ALD window for cobalt metal was observed from 280-290° C. with a growth rate of ˜0.3 Å/cycle. Films were grown on ruthenium using the following pulse sequence for 1000 cycles:

| | | | |
|---|---|---|---|
| 3 s | 10 s | 0.2 s | 10 s |
| Co pulse | N₂ purge | Me₂NNH₂ | N₂ purge |
| | | pulse | |

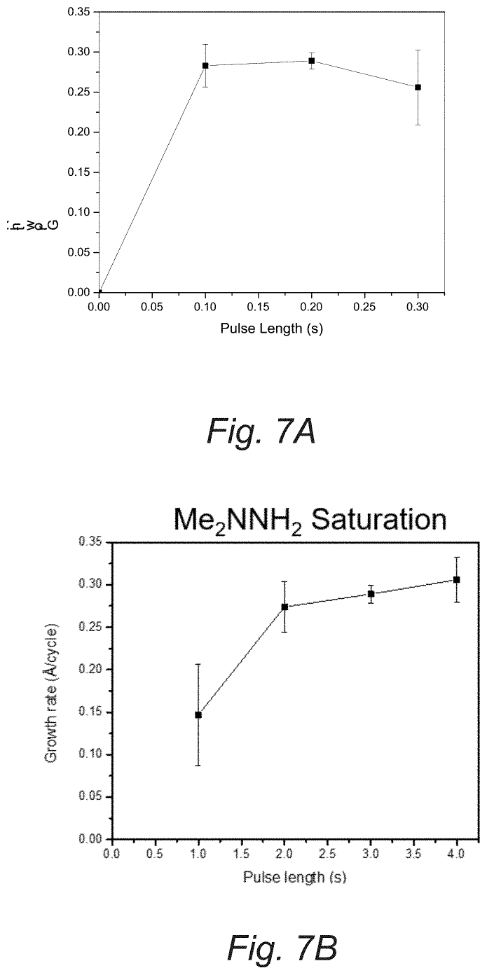

FIG. 7A provides a saturation curve for Co(thd)₂ while FIG. 7B provides a saturation curve for Me₂NNH₂. Saturation was observed for both precursors at 280° C. indicating a self-limiting growth process in the ALD window

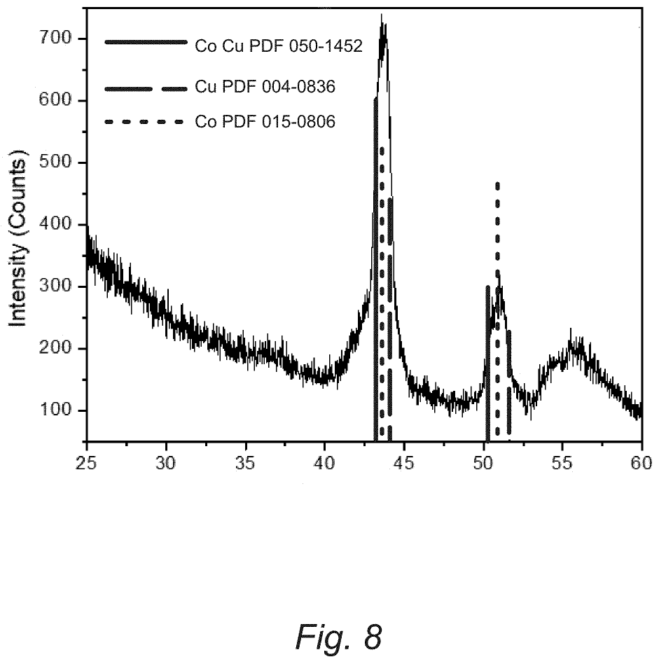

Grazing incidence X-ray diffraction data was collected for a film grown on copper for 2000 cycles. FIG. 8 provides grazing incidence X-ray diffraction data was collected for a film grown on copper for 2000 cycles. The observed reflections are consistent with cobalt metal or a cobalt-copper alloy. However, confirmation of cobalt metal deposition by X-ray diffraction is complicated by proximity of copper metal reflections

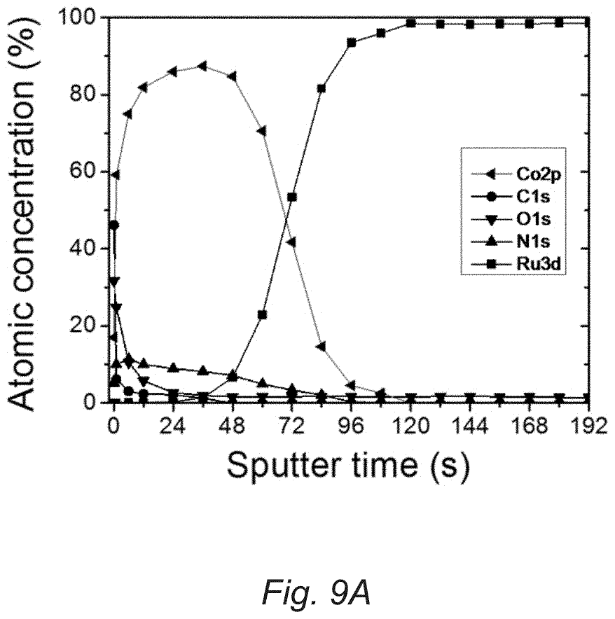

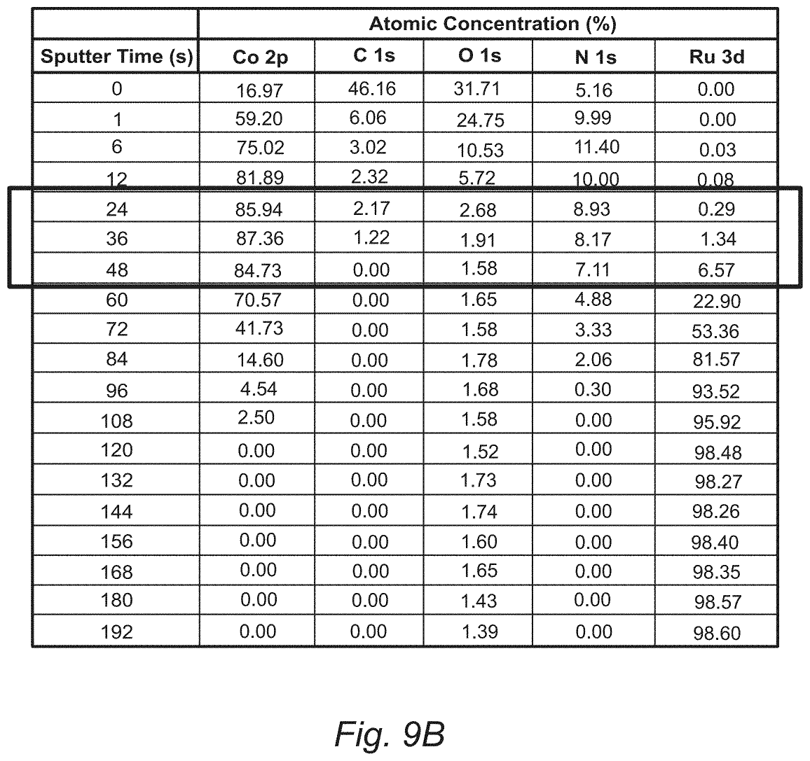

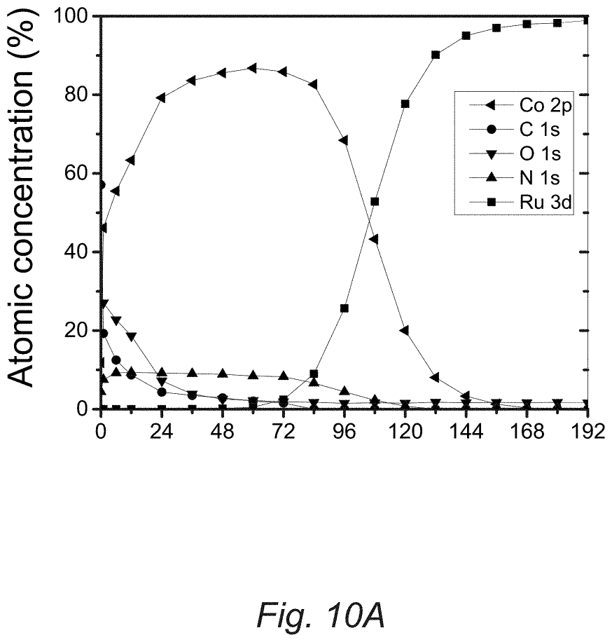

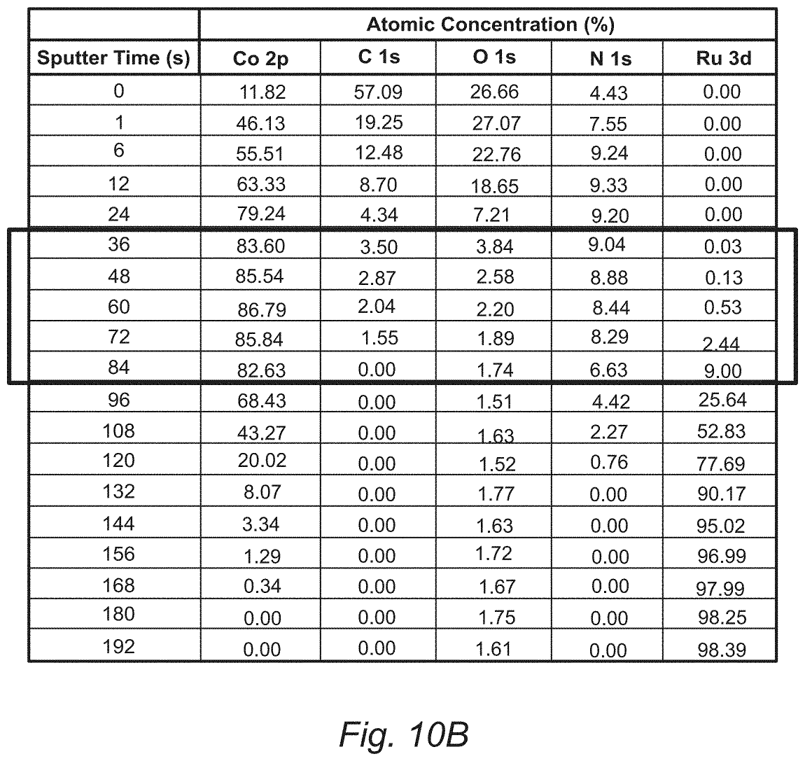

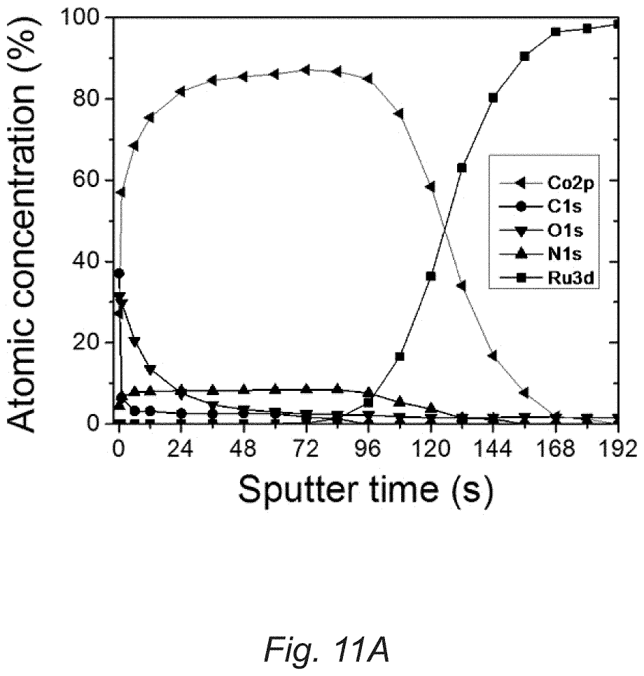

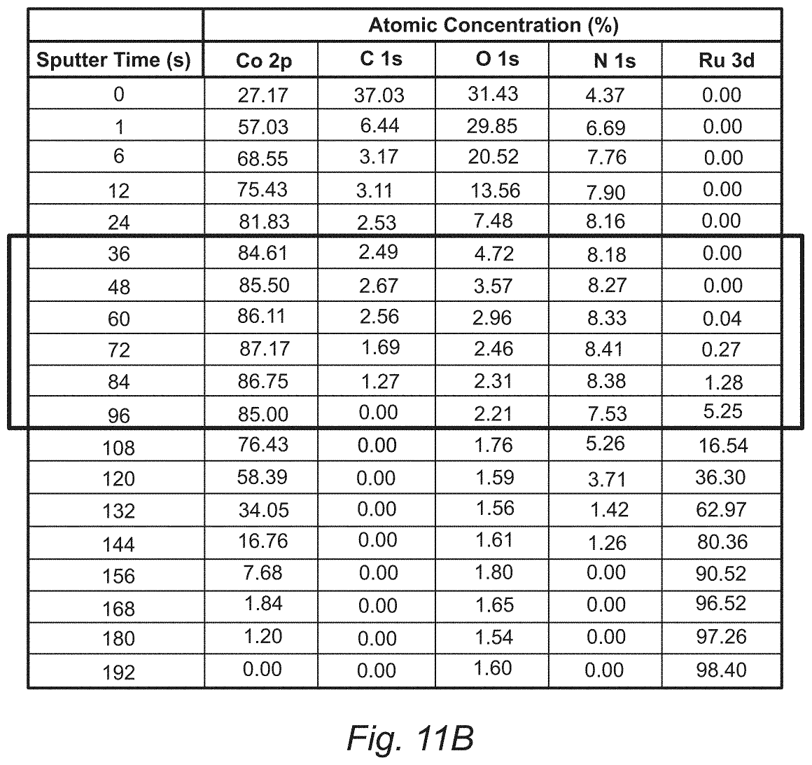

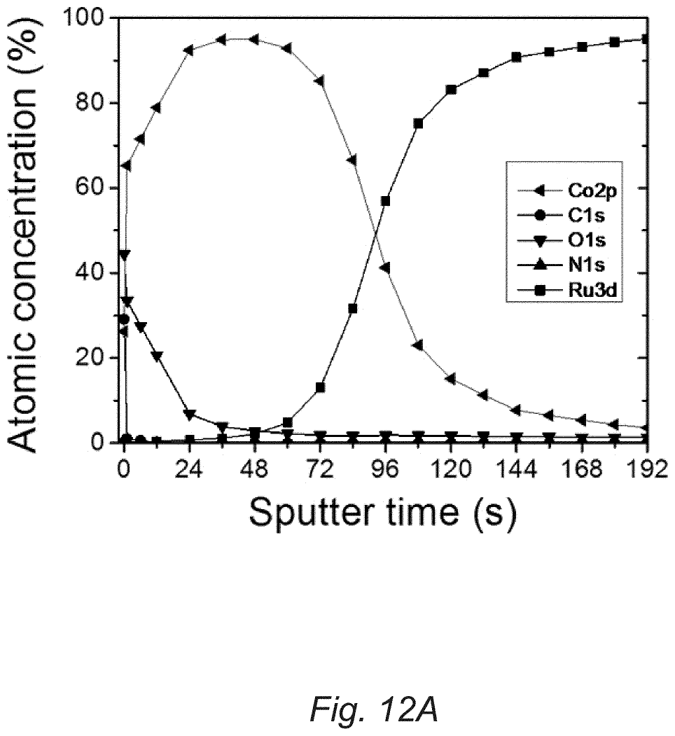

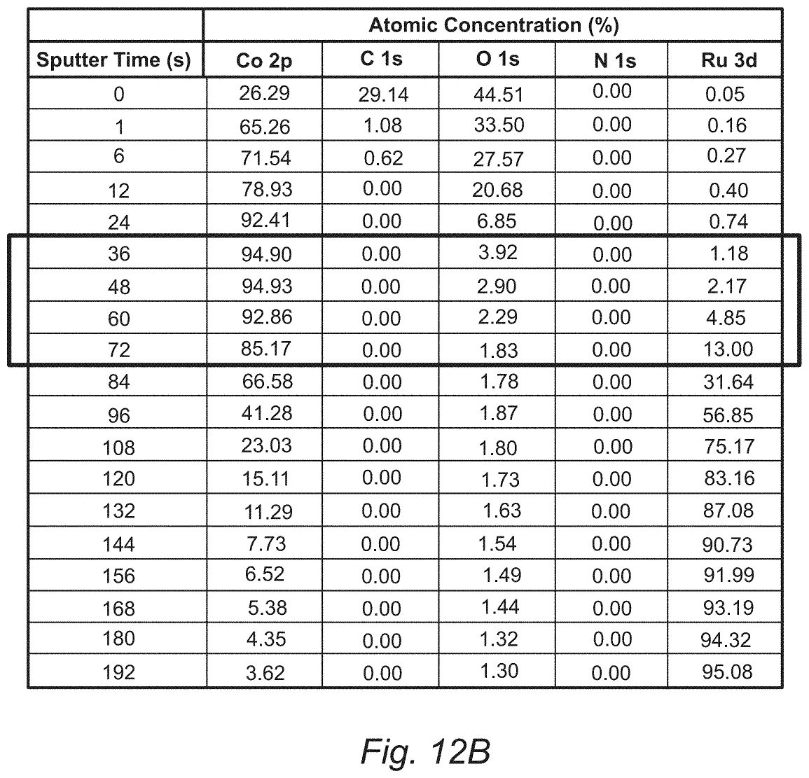

X-ray photoelectron spectroscopy depth profile data was collected for films grown at various temperatures and with a post-deposition anneal. Four films were grown using 2000 cycles and submitted for analysis: 22 nm thick film grown at 265° C.; 18 nm thick film grown at 275° C.; 38 nm thick film grown at 285° C.; and 30 nm thick film grown at 285° C.+post-deposition anneal at 400° C. All films were grown on ruthenium substrates. For this analysis, films were sputtered using a 3.0 keV argon ion beam to obtain depth profiles. FIG. 9A provides an XPS Depth Profile plots for 22 nm thick cobalt metal film deposited at 265° C. from Co(thd)₂. FIG. 9B provides an XPS Depth Profile table for 22 nm thick cobalt metal film deposited at 265° C. from Co(thd)₂. The regions showing Co metal film is selected. FIG. 10A provides an XPS Depth Profile plots for 18 nm thick cobalt metal film deposited at 275° C. from Co(thd)₂. FIG. 10B provides an XPS Depth Profile table for 18 nm thick cobalt metal film deposited at 275° C. from Co(thd)₂. The regions showing Co metal film is selected. FIG. 11A provides an XPS Depth Profile plots for 38 nm thick cobalt metal film deposited at 285° C. from Co(thd)₂. FIG. 11B provides an XPS Depth Profile table for 38 nm thick cobalt metal film deposited at 285° C. from Co(thd)₂. The regions showing Co metal film is selected. FIG. 12A provides an XPS Depth Profile plots for 30 nm thick cobalt metal film deposited at 285° C. from Co(thd)₂ with annealing. FIG. 12B provides an XPS Depth Profile table for 30 nm thick cobalt metal film deposited at 285° C. from Co(thd)₂ with annealing. The regions showing Co metal film are selected. Films grown from 265-285° C. with no post-deposition anneal had ˜8-10% nitrogen, 2-4% carbon, and ˜5% oxygen after sputtering. The film treated with post-deposition annealing at 400° C. had 0% carbon and nitrogen with ˜2% oxygen. Oxygen content in the film is likely due to the long period of air exposure between deposition and analysis. Films deposited at higher temperatures required longer sputter times, indicating the films may be denser when deposited at higher temperatures.

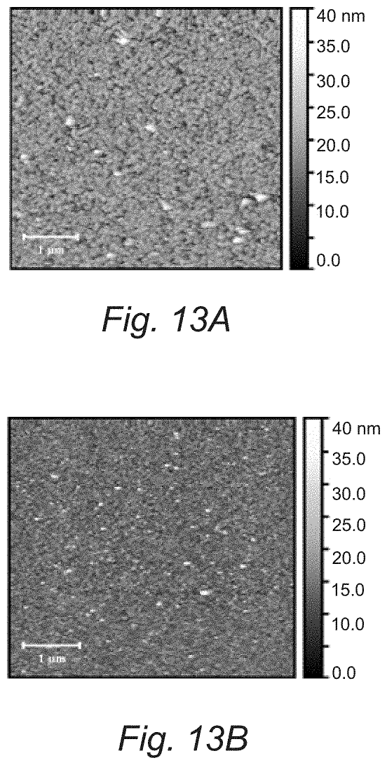

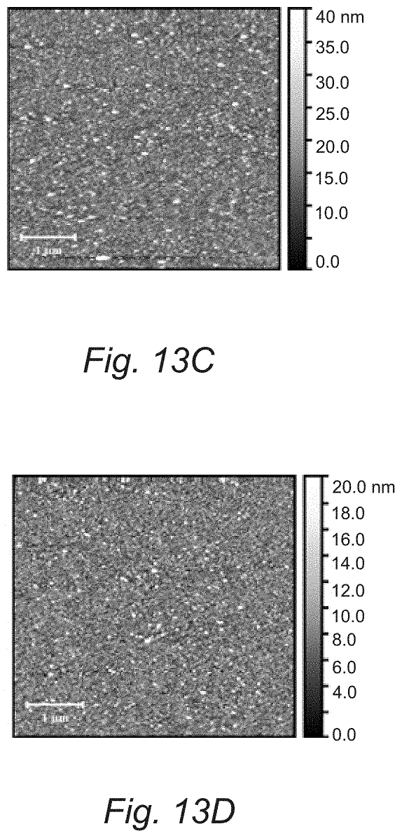

Atomic force microscopy data was also collected on samples using the deposition conditions set forth for FIGS. 9-12. FIG. 13A. Atomic Force Microscopy Data for a thick cobalt metal film deposited at 265° C. from Co(thd)₂ showing an RMS roughness value of 2.97 nm. FIG. 10B. Atomic Force Microscopy Data for a thick cobalt metal film deposited at 275° C. from Co(thd)₂ showing an RMS roughness 4.35 nm. FIG. 10C. Atomic Force Microscopy Data for a thick cobalt metal film deposited at 285° C. from Co(thd)₂ showing an RMS roughness value of 2.87 nm. FIG. 10D. Atomic Force Microscopy Data for a thick cobalt metal film deposited at 285° C. from Co(thd)₂ with a 400° C. anneal showing an RMS roughness value of 3.26 nm.

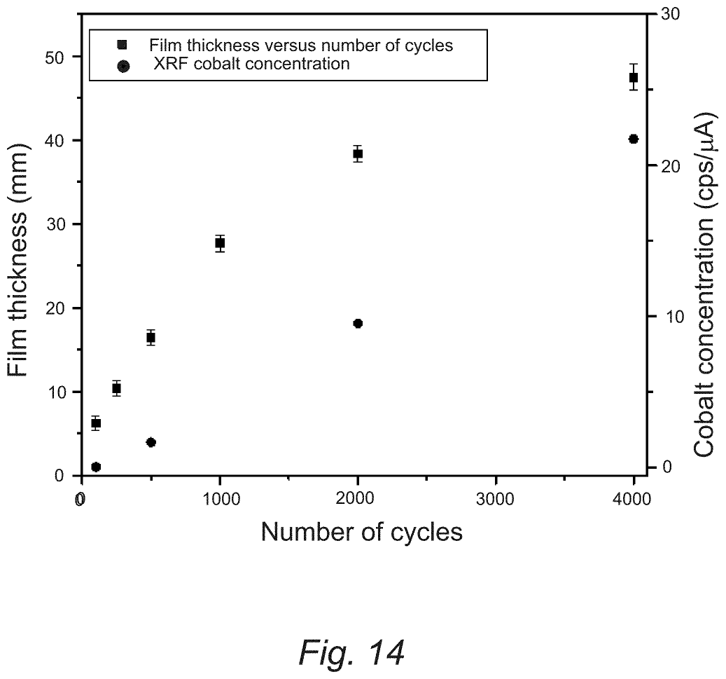

FIG. 14 provides plot of the growth rate versus number of cycles for a cobalt metal film deposited at 285° C. from Co(thd)₂. Growth behavior of the film was also analyzed with increasing numbers of ALD cycles. A linear trend was not observed. X-ray fluorescence analysis of the films shows a linear increase in the concentration of cobalt with increasing cycles. This indicates the density of the film increases with the increasing number of cycles, consistent with annealing of the film during longer deposition times.

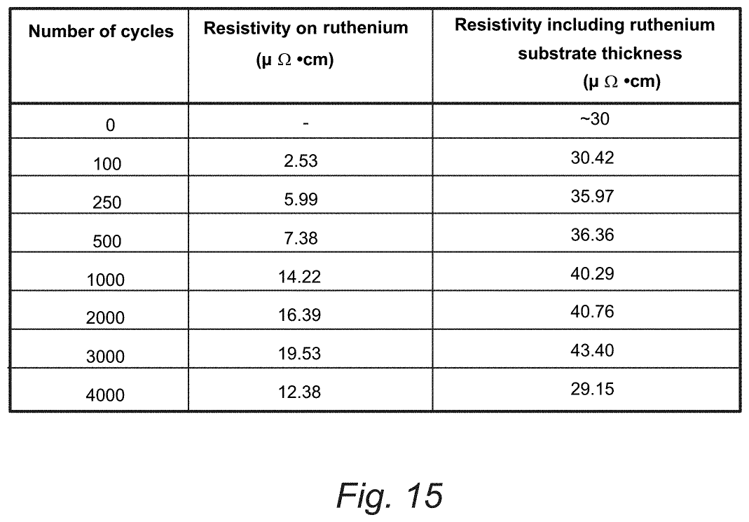

FIG. 15 provides resistivity data for films grown with an increasing number of ALD cycles. Resistivity data for films grown with an increasing number of ALD cycles is similar due to the conductivity of the underlying ruthenium. At ˜50 nm (4000 cycles), the resistivity of the film drops

In conclusion, cobalt metal has been deposited using Co(thd)₂ and 1,1-dimethyl hydrazine. GI-XRD analysis of a film grown on copper was consistent with cobalt metal or cobalt-copper alloy, XPS data indicated low levels of carbon, nitrogen, and oxygen in films deposited at various temperatures and treatment of a film with a post-deposition anneal resulted in a high-quality film with no carbon or nitrogen impurities. AFM data reveals that deposition temperature had little effect on surface roughness. There is a nonlinear relationship between film thickness and number of cycles while there is a linear increase in cobalt concentration, indicating the density of the film increases with an increasing number of cycles. Resistivity measurements are similar to the resistivity of the bare ruthenium substrates until the film thickness approaches 50 nm where it drops notably.

### EXPERIMENTAL

Cobalt diketonates,¹ amine adducts,² ketoiminates,³ and pyrazolyl borates⁴ were synthesized and purified according to general literature procedures using standard air-free Schlenk line and glovebox techniques. Co(thd)₂ (thd=2,2,6,6-tetramethylheptanedionate) required additional processing to obtain material of high enough purity for deposition. Crude Co(thd)₂ was dissolved in diethyl ether, washed with brine, dried with MgSO₄, precipitated from degassed diethyl ether at −30° C., filtered, and sublimed at 120° C./0.5 Torr. Cobalt diketiminates were synthesized by modified literature procedures using CoCl₂ in place of MnCl₂ and purified by sublimation at 134° C./0.5 Torr. Melting point measurements were taken using a Thermo Scientific Mel-temp 3.0 and are uncorrected. Thermogravimetric analysis experiments were conducted on a TA Instruments SPT 2960 with a heating rate of 5° C./min.

Atomic layer deposition experiments were performed on a Picosun R200 ALD reactor operating at 6-10 Torr from 200-300° C. on Ru (35 or 45 nm), Cu (30 nm), Pt (100 nm), SiO₂, high resistivity Si, and in situ ALD TiN² substrates. Cobalt precursors were delivered using a Picosolid booster. Nitrogen-based co-reactants were used as received from Sigma-Aldrich and delivered using a vapor draw bubbler. A flow restricting VCR gasket (100 μm) installed in the bubbler line was used to limit co-reactant consumption. Ultrahigh purity N₂ (99.999%, Airgas) was used as the carrier and purge gas. Cobalt metal was deposited using Co(thd)₂ and 1,1-dimethyl hydrazine (DMH) from 265-300° C. using the following pulse sequence: Co(thd)₂ (3.0 s), N₂ purge (10 s), DMH (0.2 s), N₂ purge (10 s). Co(thd)₂ was delivered to the reaction chamber at 130° C. and DMH was delivered at ambient temperature (˜22° C.). Except for a film submitted for XPS analysis, Co films were not subjected to any post-deposition treatment. Annealing for XPS experiments was completed immediately following deposition by heating the reaction chamber to 400° C. for ˜3 h.

Film thicknesses were measured by cross-sectional scanning electron microscopy experiments using a JEOL-6510LV scanning electron microscope. Sheet resistance was measured at room temperature using a Jandel RM3000+ four-point probe. X-ray fluorescence measurements were completed using a Shimadzu EDX-7000. Atomic force microscopy (AFM) measurements were conducted using a VEECO Dimension 3100 atomic force microscope operated in tapping mode. NanoScope (version 5.31R1) was used to collect the data. Gwyddion (version 2.44) was used to calculate the root mean square (RMS) roughness values and generate images of the surfaces (512-pixel resolution).

X-ray photoelectron spectroscopy (XPS) measurements used an Al Kα (1486.6 eV) X-ray source (pass energy=23.5 eV, step size=0.200 eV) at a chamber base pressure of 10⁻¹⁰ Torr. Spectra were recorded using a 16-channel detector with a hemispherical analyzer using a PHI 5000 VersaProbe II XPS instrument. An XPS software package (MultiPak, version 9.4.0.7) was used to collect the data focusing on the Co 2p, O Is, N Is, C Is, Ru 3p, and Ru 3d core levels. Sputtering was performed over a 2×2 mm² area using 3 keV argon ions supplied by an argon sputter gun positioned at a 45° angle with respect to the substrate normal. Measurements were made over a 0.2×0.2 mm² area. All spectra are uncorrected. Peak fitting was performed with CasaXPS (version 2.3.17PR1.1) using absolute sensitivity factors (ASF) for Co 2p (3.590), O is (0.711), N is (0.477), C is (0.296), and Ru 3d (4.273).³ Spectra of ALD-grown films were fit using the models and constraints derived from fitting the spectra of cobalt and ruthenium metal standards. Cobalt 2p ionizations were modeled using a doublet with a Lorentzian (LA) lineshape for the metallic contribution (area ratio=1:2, Δ=15.1 eV), a Gaussian Lorentzian (GL) lineshape for the Auger feature, and a pair of doublets with GL lineshapes for the oxide contribution (area ratio=1:2). Ruthenium 3d ionizations were modeled using a doublet with a Lorentzian damped tail (LF) lineshape (area ratio=2:3, Δ=4.2 eV). Carbon, nitrogen, and oxygen ionizations were modeled using three GL lineshapes each. A Shirley background was used for all spectra.

While exemplary embodiments are described above, it is not intended that these embodiments describe all possible forms of the invention. Rather, the words used in the specification are words of description rather than limitation, and it is understood that various changes may be made without departing from the spirit and scope of the invention. Additionally, the features of various implementing embodiments may be combined to form further embodiments of the invention.

### REFERENCES

1. Caneschi, A.; Gatteschi, D.; Laugier, J.; Rey, P.; Sessoli, R. Inorg. Chem. 1988, 27, 1553-1557.
2. Colbern, R. E.; Garbauskas, M. F.; Hejna, C. I. Inorg. Chem. 1988, 27, 3661-3663.
3. Puring, K.; Zywitzki, D.; Taffa, D. H.; Rogalla, D.; Winter, M.; Mark, M.; Devi, A. Inorg. Chem. 2018, 57, 5133-5144
4. Trofimenko, S. J. Am. Chem. Soc. 1967, 89, 13, 3170-3177.
5. Stalzer, M. M.; Lohr, T. L.; Marks, T, J. Inorg. Chem. 2018, 57, 3017-3024.
6. Wolf, M. Breeden, I. Kwak, J. H. Park, M. Kavrik, M. Naik, D. Alvarez, J. Spiegelman, and A. C. Kummel, Appl. Surf Sci. 2018, 462, 1029-1035.
7. Moulder, J. F.; Stickle, W. F.; Sobol, P. E.; Bomben, K. D. Handbook of X-Ray Photoelectron Spectroscopy; Perkin-Elmer Corp.: Eden Prairie, Minn., 1992.

What is claimed is:

1. A method for depositing a metal layer, the method comprising:
a) contacting a surface of an electrically conductive substrate with a vapor of a metal-containing compound for a first predetermined pulse time to form a modified surface on the electrically conductive substrate, the metal-containing compound being described by formulae 1.1 or 1.2 or oligomers thereof: 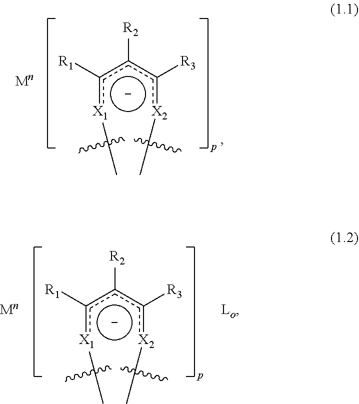
wherein:
M is a metal atom;
n is the formal charge of M;
X₁ and X₂ are each independently O or N—R₄;
L is a neutral or anionic ligand;
o is 1, 2, or 3;
p is an integer such that the overall formal charge of the metal-containing compound is 0;
R₁, R₂, R₃, and R₄ are each independently H, C₁-C₅ alkyl, perfluorinated C₁-C₅ alkyl, partially fluorinated C₁-C₅ alkyl, or —Si(R⁵)₃; and
R⁵ is H, halo, C₁-C₅ alkyl, perfluorinated C₁-C₅ alkyl, or partially fluorinated C₁-C₅ alkyl; and
b) contacting the modified surface with a vapor of a reducing agent having formula 2 for a second predetermined pulse time to form a metal-containing film on the surface of the electrically conductive substrate, the metal-containing film including the metal atom in a zero oxidation state in an amount greater than 80 mole percent: 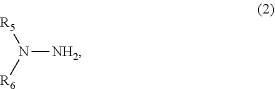
wherein R⁵ and R⁶ are each independently H or C₁-C₅ alkyl and wherein the electrically conductive substrate is at a first predetermined temperature during steps a) and b).

2. The method of claim 1 wherein the metal-containing film includes metastable metal nitrides in an amount less than 20 mole percent.

3. The method of claim 1 wherein the first predetermined temperature is from about 200 to 350° C. and wherein steps a) and b) are performed at a first predetermined pressure of about 0.1 millitorr to 100 Torr.

4. The method of claim 1 further comprising a step of annealing the metal-containing film at a second predetermined temperature for a sufficient time that the metal-containing film includes the metal atom in the zero oxidation state in an amount greater than 98 mole percent, the second predetermined temperature is greater than the first predetermined temperature.

5. The method of claim 1 wherein R₁, R₂, R₃, and R₄ are each independently H, methyl, ethyl, propyl, n-butyl, sec-butyl, isobutyl, or t-butyl.

6. The method of claim 1 wherein the reducing agent is tBuNHNH₂, (CH₃)₂NNH₂, or H₂NNH₂.

7. The method of claim 1 wherein M is a transition metal atom.

8. The method of claim 1 wherein the metal-containing compound is described by formulae 2.1 and 2.2:

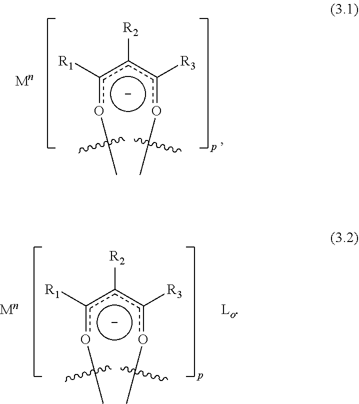

9. The method of claim 1 wherein the metal-containing compound is described by formulae 2.3:

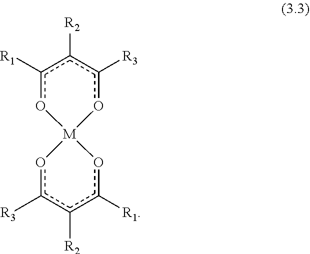

10. The method of claim 9 wherein M is Co, Cr, Mn, Fe, Zn, or Ni.

11. The method of claim 1 wherein the electrically conductive substrate includes one or more electrically conductive films disposed over a base substrate such that the metal-containing film grows selectively on surfaces of the one or more electrically conductive films.

12. The method of claim 1 wherein the electrically conductive substrate has an electrical resistivity less than about 1×10⁻² ohm-m.

13. The method of claim 12 wherein the electrically conductive substrate includes one or more surfaces composed of silicon, titanium nitride, tantalum nitride, or a metal.

14. The method of claim 1 wherein the electrically conductive substrate includes one or more surfaces composed of copper or ruthenium.

15. The method of claim 1 wherein steps a) and b) are repeated a plurality of times in an atomic layer deposition reactor.

16. A method for depositing a metal layer, the method comprising:
a) contacting a surface of an electrically conductive substrate with a vapor of a metal-containing compound for a first predetermined pulse time to form a modified surface on the electrically conductive substrate, the metal-containing compound being described by formula 2.3: 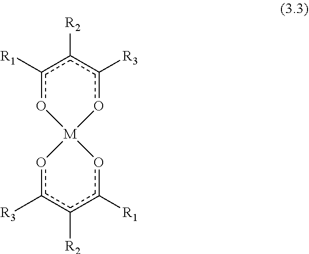
wherein:
M is a metal atom selected from the group consisting of Co, Cr, Mn, Fe, Zn, or Ni; and
R₁, R₂, and R₃ are each independently H, C₁-C₅ alkyl, perfluorinated C₁-C₅ alkyl, partially fluorinated C₁-C₅ alkyl, or —Si(R⁴)₃; and
and
b) contacting the modified surface with a vapor of a reducing agent having formula 2 for a second predetermined pulse time to form a metal-containing film on the surface of the electrically conductive substrate, the metal-containing film including the metal atom in a zero oxidation state in an amount greater than 80 mole percent: 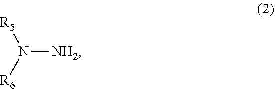
wherein R⁵ and R⁶ are each independently H or C₁-C₅ alkyl,
wherein the electrically conductive substrate is at a first predetermined temperature during steps a) and b) and wherein steps a) and b) are performed a plurality of times until the metal-containing film is within a predetermined thickness range.

17. The method of claim 16 wherein the metal-containing film includes metastable metal nitrides in an amount less than 20 mole percent.

18. The method of claim 17 wherein the first predetermined temperature from about 200 to 350° C. and wherein steps a) and b) are performed at a first predetermined pressure of about 0.1 millitorr to 100 Torr.

19. The method of claim 16 further comprising a step of annealing the metal-containing film at a second predetermined temperature for a sufficient time that the metal-containing film includes the metal atom in the zero oxidation state in an amount greater than 98 mole percent, the second predetermined temperature is greater than the first predetermined temperature.

20. The method of claim 16 wherein the reducing agent is tBuNHNH₂, (CH₃)₂NNH₂, or H₂NNH₂.

21. The method of claim 16 wherein the electrically conductive substrate includes one or more electrically conductive films disposed over a base substrate.

22. The method of claim 21 wherein the metal-containing film grows selectively on surfaces of the one or more electrically conductive films.
